(19) United States
(12) Patent Application Publication
(10) Pub. No.: US 2009/0075179 A1
(43) Pub. Date: Mar. 19, 2009

(54) EXTREME ULTRAVIOLET (EUV) MASK PROTECTION AGAINST INSPECTION LASER DAMAGE

(76) Inventors: Erdem Ultanir, San Carlos, CA (US); Pei-Yang Yan, Saratoga, CA (US)

Correspondence Address: COOL PATENT, P.C.;c/o INTELLEVATE, P.O. BOX 52050, MINNEAPOLIS, MN, 55402, US

(21) Appl. No.: 11/857,131

(22) Filed: Sep. 18, 2007

(51) Int. Cl. G03F 1/00

(52) U.S. Cl. 430/5

(57) ABSTRACT

Extreme Ultraviolet (EUV) mask protection against laser inspection damage is generally described. In one example, a photomask includes a substrate, a bilayer stack coupled with the substrate, the bilayer stack including about 30-50 bilayers wherein the bilayers include alternating films of a first material and a second material, a protective film including polycrystalline carbon coupled with the bilayer stack to protect the bilayer stack against laser inspection damage, and a capping film coupled with the protective film.

### BACKGROUND

Generally, the quality of an extreme ultraviolet (EUV) photomask directly affects the performance of semiconductor devices made using the mask. Currently, EUV photomask blanks may be inspected for defects prior to deposition and patterning of an absorber layer. EUV photomask inspection tools may include high power confocal microscopes that use deep ultraviolet (DUV) radiation such as a DUV laser to detect defects larger than about 30 nm on the mask.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is an EUV photomask layer schematic for protecting an EUV photomask against inspection laser damage, according to but one embodiment;

FIG. 2 is a method for making an EUV photomask having protection against inspection laser damage, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of Extreme Ultraviolet (EUV) photomask protection against inspection laser damage are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

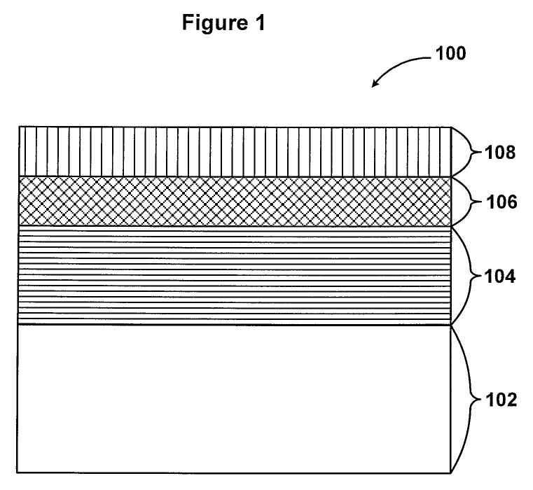

FIG. 1 is an EUV photomask layer schematic for protecting an EUV photomask against inspection laser damage 100, according to but one embodiment. In an embodiment, a photomask 100 includes a substrate 102, bilayer stack 104, protective carbon film 106, and capping film 108, each coupled as shown. In another embodiment, apparatus 100 includes an absorber film coupled with the capping film. The absorber film may be patterned with circuit features and/or other features to be transferred to a surface of a semiconductor wafer to fabricate semiconductor devices.

Currently, EUV photomask blanks may be inspected for defects prior to deposition and patterning of an absorber layer. EUV photomask inspection tools may include high power confocal microscopes that use deep ultraviolet (DUV) radiation such as a DUV laser to detect defects larger than about 30 nm on the mask. Such DUV inspection may cause oxygen diffusion below a capping layer of the EUV photomask resulting in damage to the mask. DUV laser inspection may particularly cause damage to a region between about 0-20 nm deep into the capping layer side of the mask resulting in oxidation or other reactions between the materials of the capping layer and alternating bilayer stack.

DUV laser inspection may promote oxide growth between a capping layer and a bilayer stack. In one example, a single capping layer such as ruthenium having a thickness of about 2.5 nm is not sufficient to protect the bilayer stack against inspection at 266 nm and about 500 mW of power. The above-described reactions or damage may result in loss of reflectivity, defects, or other undesirable optical qualities. Defect sensitivity and mask damage may increase with increasing inspection tool power. Also, defect sensitivity and mask damage may increase with decreasing wavelength. Decreasing the power of the inspection tool to avoid such damage results in a loss of inspection sensitivity that may result in an ineffective inspection of the mask.

According to an embodiment, a photomask 100 provides protection against inspection laser damage by inclusion of a protective carbon layer 106 between the capping layer 108 and bilayer stack 104. In an embodiment, a photomask includes a substrate 102, a bilayer stack 104 coupled with the substrate 102, the bilayer stack 104 comprising 30-50 bilayers wherein the bilayers include alternating films of a first material and second material, a protective film 106 of carbon coupled with the bilayer stack 104 to protect the bilayer stack 104 against laser inspection damage, and a capping film 108 coupled with the protective film 106. In an embodiment, the protective film 106 consists essentially of polycrystalline carbon. In another embodiment, the protective film 106 is atomic or elemental carbon. In yet another embodiment, the protective film 106 is substantially free of any material except for carbon.

According to an embodiment, a protective film 106 of carbon is about 0.5 nm to 3 nm thick. Such thicknesses may reduce DUV inspection laser damage to a photomask 100 having a ruthenium (Ru) capping layer that is about 2.5 nm thick. In another embodiment, a protective film 106 of carbon reduces the diffusion of oxygen under the capping layer 108. In an embodiment, a protective film 106 of carbon behaves as a barrier and reduces damage to a photomask 100 caused by oxygen diffusion under the capping layer 108. In an embodiment, a photomask 100 having a 2.5 nm thick Ru capping layer 108 and a 2 nm thick protective carbon layer 106 shows a drop of about 0.2% absolute reflectance after ten inspections with a 266 nm wavelength, 500 mW power confocal microscope while a photomask only having a 2.5 nm thick Ru capping layer and no protective carbon layer shows a drop of about 1.7% after ten inspections.

A protective film 106 of carbon may enable the use of a 266 nm wavelength, 500 mW power mask inspection tool for EUV photomask blanks 100 prior to patterning. By reducing the amount of damage to a mask 100, a protective film 106 of carbon may enable the use of smaller wavelengths and/or higher power defect inspections, or suitable combinations thereof. In an embodiment, a protective film 106 of carbon is deposited by molecular beam epitaxy, sputtering, atomic layer deposition (ALD), physical vapor deposition (PVD), chemical vapor deposition (CVD), any other suitable mask-making film deposition method, or suitable combinations thereof.

Other mask materials may include a capping film 108 including ruthenium wherein the capping film is about 2.5 nm thick. A substrate 102 may include quartz, fused silica, a low thermal expansion material (LTEM), or suitable combinations thereof. A bilayer stack 104 may include about 40 bilayers of an alternating first and second material. In an embodiment, a bilayer stack 104 includes a first material including molybdenum and a second material including silicon. In another embodiment, a bilayer stack 104 includes a first material including silicon and a second material including molybdenum. A bilayer stack 104 may form a multilayer structure where EUV light reflectance is increased through constructive interference. The effect of the first couple of bilayers 104 on constructive interference may be larger than the rest of the stack, therefore protection of the part of the multilayer coating 104 closest to the capping film 108 may be important to avoid a drop in reflection.

An absorber layer or film may be coupled with the capping film 108 to absorb EUV light. An absorber film may include TaN and may be patterned with a chip design or layout to be transferred onto semiconductor wafers. An absorber film may be patterned by e-beam or other suitable mask-patterning method. The inclusion of a protective film 106 of carbon as described herein may not require changing current mask patterning processes on the absorber film.

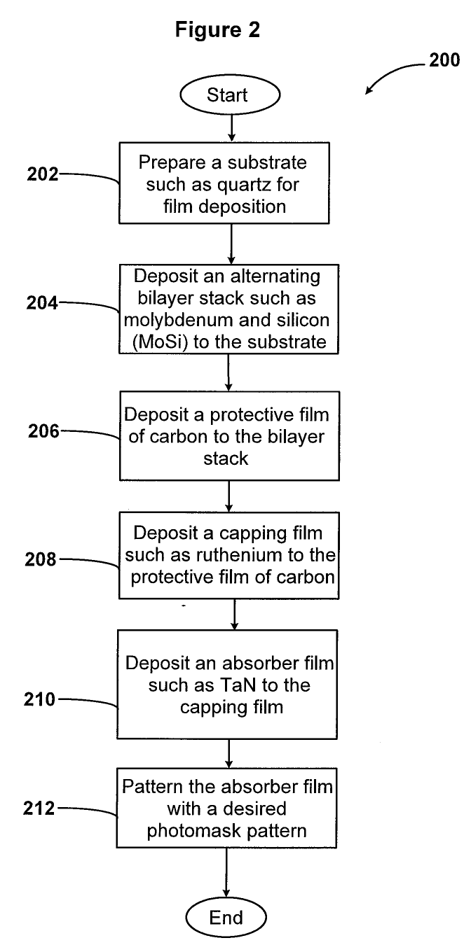

FIG. 2 is a method for protecting an EUV photomask against inspection laser damage 200, according to but one embodiment. In an embodiment, a method 200 includes preparing a substrate such as quartz for film deposition 202, depositing an alternating bilayer stack such as molybdenum and silicon (MoSi) to the substrate 204, depositing a protective film of carbon to the bilayer stack 206, depositing a capping film such as ruthenium to the protective film of carbon 208, depositing an absorber film such as TaN to the capping film 210, and patterning the absorber film with a desired photomask pattern 212, with arrows providing a suggested flow.

In an embodiment, a method includes 200 depositing a bilayer stack to a substrate 204, the bilayer stack including 30-50 bilayers wherein the bilayers include alternating films of a first material and second material. A method 200 may further include depositing a protective film 206 consisting substantially of polycrystalline carbon to the bilayer stack such that the protective film protects the bilayer stack against laser inspection damage. A method 200 may further include depositing a capping film to the protective film 208. A capping film of ruthenium may be about 2.5 nm thick.

In an embodiment, depositing a protective film 206 includes depositing a protective film of carbon having a thickness of about 0.5 to 3 nm. In another embodiment, the depositing a protective film of carbon 206 reduces diffusion of oxygen under the capping layer. Depositing a protective film of carbon 206 may enable the use of a laser inspection tool utilizing a laser with a wavelength of about 266 nm and about 500 mW of power by reducing the amount of damage to a mask. By reducing the amount of damage to a mask, depositing a protective film 206 of carbon may also enable the use of smaller wavelengths and/or higher power defect inspections, or suitable combinations thereof.

In one embodiment, depositing a protective film 206 includes depositing by molecular beam epitaxy, sputtering, atomic layer deposition (ALD), physical vapor deposition (PVD), chemical vapor deposition (CVD), any suitable deposition method, or suitable combinations thereof. Other embodiments for depositing a protective film of carbon 206 and/or other actions in method 200 also incorporate embodiments already described herein for a photomask 100.

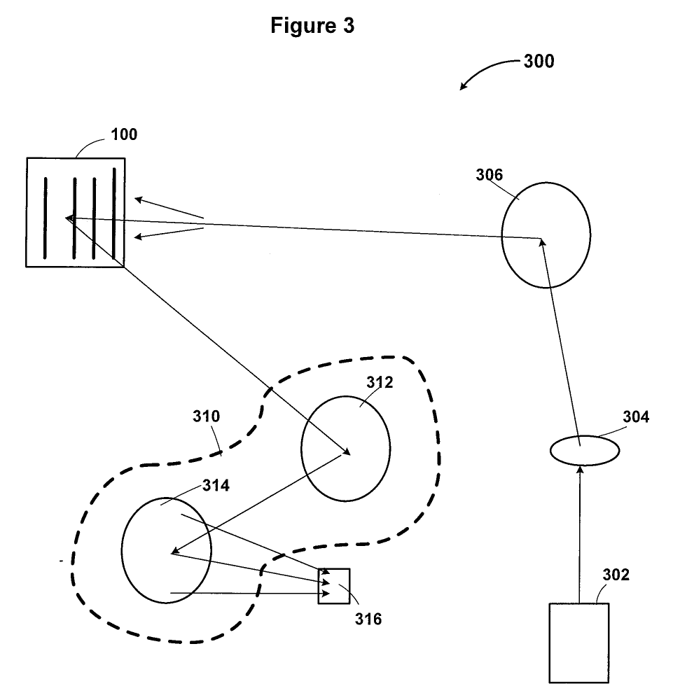

FIG. 3 is a diagram of an example system in which embodiments of the present invention may be used 300, according to but one embodiment. In an embodiment, system 300 is an EUV lithography system comprising laser 302, plasma 304, optical condenser 306, photomask 100, reduction optics 310, and semiconductor substrate 316, each coupled as shown. In an embodiment, system 300 is an EUV stepper or scanner. Arrows may suggest a radiation pathway through the system 300. Although an EUV lithography system 300 is shown here as an example, embodiments disclosed herein may apply to other lithography platforms such as x-ray lithography for example.

In an embodiment, a laser 302 generates a laser beam to bombard a target material, which produces plasma 304 with significant broadband extreme ultra-violet (EUV) radiation. An optical condenser 306 may collect the EUV radiation through mirrors coated with EUV interference films such as Ru. The optical condenser 306 may illuminate a reflective mask 100 with EUV radiation of about 13 nm wavelength. In an embodiment, a reflective mask 100 accords with embodiments described with respect to FIGS. 1-2. Mask 100 may have an absorber pattern across its surface, which may comprise one or more integrated circuit designs. The pattern may be typically imaged at 4:1 demagnification by the reduction optics 310. The reduction optics 310 may include mirrors such as mirrors 312 and 314. These mirrors, for example, may be aspherical with tight surface figures and roughness (e.g., less than 3 Angstroms).

In an embodiment, a semiconductor substrate 316 is coated with resist that is sensitive to EUV radiation. The semiconductor substrate 316 may be a silicon-based wafer. The resist may be imaged with the pattern on the reflective mask 308. Typically, a step-and-scan exposure may be performed, i.e., the photomask 308 and the substrate 316 are synchronously scanned. Using this technique, a resolution less than 50 nm may be possible. The dimensions may not be scaled in the illustrative figure.

Various operations in methods described herein may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. A photomask comprising:
a substrate;
a bilayer stack coupled with the substrate, the bilayer stack comprising about 30-50 bilayers wherein the bilayers comprise alternating films of a first material and a second material;
a protective film consisting substantially of polycrystalline carbon coupled with the bilayer stack to protect the bilayer stack against laser inspection damage; and
a capping film coupled with the protective film.

2. A photomask according to claim 1 wherein the protective film of carbon is about 0.5 nm to 3 nm thick and wherein the protective film of carbon is capable of reducing diffusion of oxygen under the capping layer.

3. A photomask according to claim 1 wherein the protective film is capable of protecting the bilayer stack from radiation having a wavelength of about 266 nm or less, or a power of about 500 mW or greater, or suitable combinations thereof.

4. A photomask according to claim 1 wherein the protective film of carbon is deposited by molecular beam epitaxy, sputtering, atomic layer deposition (ALD), physical vapor deposition (PVD), chemical vapor deposition (CVD), or suitable combinations thereof.

5. A photomask according to claim 1 wherein the capping film comprises ruthenium and wherein the capping film is about 2.5 nm thick.

6. A photomask according to claim 1 wherein the substrate comprises quartz, fused silica, low thermal expansion material (LTEM), or suitable combinations thereof.

7. A photomask according to claim 1 wherein the bilayer stack comprises 40 bilayers and wherein the first material of the bilayer stack comprises molybdenum and the second material of the bilayer stack comprises silicon.

8. A photomask according to claim 1 further comprising:
an absorber film coupled with the capping film, the absorber film comprising TaN.

9. A method comprising:
depositing a bilayer stack to a substrate, the bilayer stack comprising 30-50 bilayers wherein the bilayers comprise alternating films of a first material and second material;
depositing a protective film consisting substantially of polycrystalline carbon to the bilayer stack wherein the protective film protects the bilayer stack against laser inspection damage; and
depositing a capping film to the protective film.

10. A method according to claim 9 wherein depositing a protective film comprises depositing a protective film of carbon having a thickness of about 0.5 nm to 3 nm wherein the protective film reduces diffusion of oxygen under the capping layer and enables the use of a laser inspection tool upon the capping layer or bilayer stack, the laser inspection tool utilizing a laser with a wavelength of about 266 nm and about 500 mW of power.

11. A method according to claim 9 wherein depositing a protective film comprises molecular beam epitaxy, sputtering, atomic layer deposition (ALD), physical vapor deposition (PVD), chemical vapor deposition (CVD), or suitable combinations thereof

12. A method according to claim 9 wherein depositing a capping film comprises depositing a capping film comprising ruthenium, the capping film being about 2.5 nm thick.

13. A method according to claim 9 wherein the substrate comprises quartz, fused silica, low thermal expansion material (LTEM), or suitable combinations thereof.

14. A method according to claim 9 wherein depositing a bilayer stack comprises depositing 40 bilayers wherein the first material of the bilayer stack comprises molybdenum and the second material of the bilayer stack comprises silicon.

15. A method according to claim 9 further comprising:
depositing an absorber layer to the capping film, the absorber layer comprising TaN.
